(19) United States
(12) Patent Application Publication
(10) Pub. No.: US 2013/0063191 A1
(43) Pub. Date: Mar. 14, 2013

(54) Methods and Circuits for Duty-Cycle Correction

(71) Applicants: Dinesh Patil, Sunnyvale, CA (US); Mohammad Hekmat, Mountain View, CA (US); Kambiz Kaviani, Palo Alto, CA (US); Amir Amirkhany, Sunnyvale, CA (US)

(72) Inventors: Dinesh Patil, Sunnyvale, CA (US); Mohammad Hekmat, Mountain View, CA (US); Kambiz Kaviani, Palo Alto, CA (US); Amir Amirkhany, Sunnyvale, CA (US)

(73) Assignee: Rambus Inc., Sunnyvale, CA (US)

(21) Appl. No.: 13/612,540

(22) Filed: Sep. 12, 2012

Related U.S. Application Data
(60) Provisional application No. 61/534,676, filed on Sep. 14, 2011.

(51) Int. Cl. H03K 3/017; H03L 7/08

(52) U.S. Cl. 327/156; 327/175

(57) ABSTRACT

A duty-cycle correction circuit calibrates the duty cycle of a periodic input signal. The correction circuit includes a state machine that samples the input signal using a sample signal of a sample period. The sample period is selected to scan a period of the input signal over a number of sample periods. The resultant difference between the number of high and low samples provides a measure of the duty cycle deviation from e.g. 50%. An adjustable delay circuit adjusts the relative timing of the rising and falling edges of the input signal, and thus the duty cycle, responsive to the measure of duty cycle.

### TECHNICAL FIELD

The subject matter presented herein relates generally to duty-cycle correction, and in particular to circuits and methods for measuring, adjusting, and maintaining a desired duty cycle for a clock signal.

### BACKGROUND

Periodic events are often characterized as having a “duty cycle,” which is the ratio of the duration of the event to the total period. Consider clock signals, for example, which are commonly used to time events on integrated circuits. Clock signals transition regularly between high and low voltage levels, and the transitions can be used as timing references. The duty cycle of a clock signal is the ratio of the amount of time the clock signal remains at the high voltage level relative to the total period of the clock. A clock signal that remains high 30% of the time has a 30% duty cycle, for example.

Many synchronous circuits are timed to just one type of clock edge, such as every rising edge. In that case, the spacing between rising edges, the clock period, is important to ensure precise timing. Because falling edges are not used, in this example, the spacing between adjacent rising and falling edges of less importance. Some circuits are timed to both rising and falling edges of a clock signal, however, in which case the spacing between adjacent rising and falling edges is ideally uniform, which is to say that the duty cycle should be 50%.

### BRIEF DESCRIPTION OF THE FIGURES

FIG. 1 depicts a duty-cycle correction circuit (DCCC) 100 that corrects for duty-cycle distortion that can result from variations in IC processing, supply voltage, and temperature.

FIG. 2 is a waveform diagram 200 illustrating the operation of an embodiment of state machine 105 of FIG. 1.

FIG. 3 depicts an embodiment of delay circuit 115 of FIG. 1, which includes a series of P current-starved inverters 300.

FIG. 4 depicts a duty-cycle adjustment circuit 400 that can be used in place of delay circuit 115 of FIG. 1 in one embodiment.

FIG. 5A is a waveform diagram depicting how an AND function can be used to adjust the duty cycle of a periodic signal.

FIG. 5B is a waveform diagram depicting how an OR function can be used to adjust the duty cycle of a periodic signal.

FIG. 6 depicts a timing circuit 600 for generating sample clock signals CKref and CKsam in accordance with one embodiment.

The figures are illustrations by way of example, and not by way of limitation. Like reference numerals in the figures refer to similar elements.

### DETAILED DESCRIPTION

FIG. 1 depicts a duty-cycle correction circuit (DCCC) 100 that corrects for duty-cycle distortion. DCCC 100 creates a balanced (50% duty cycle) input clock CKin from an unbalanced reference clock signal CKref. To do this, DCCC 100 includes a state machine 105 that measures the duty cycle of input signal CKin and develops a digital calibration signal Dcal based on that measure. A digital-to-analog converter (DAC) 110 converts digital calibration signal Dcal into an analog calibration signal Vcal and feeds the analog signal into an adjustable delay circuit 115. Delay circuit 115, responsive to signal Vcal, controls the relative delays of rising and falling edges of reference clock signal CKref to bring signal CKin closer to the target duty cycle.

State machine 105 includes two input clock nodes, one to receive input clock signal CKin and another to receive a sample clock signal CKsam from a clock source 120. State machine 105 additionally includes a sampler 125, an accumulator 130, a counter 135, and a register 140.

Sampler 125 samples clock signal CKin on rising edges of sample clock signal CKsam. In this embodiment, sample clock signal CKsam has a period Tsam that can be specified using the following equation:

Tsam=Tin(M±1/N) (1)

where Tin is the clock period of clock signal CKin. M is an integer, five in this example, that provides a gross measure of the period of sample clock CKsam relative to signal CKin. In general, higher sample-clock frequencies resolve duty cycles more quickly but require increased power consumption and impose greater design constraints on source 120 and associated logic and routing. Furthermore, as the frequency of clock signal CKin increases, it may be difficult to generate a sample-clock having a frequency higher than the clock signal. Variable M can be selected to achieve a desired balance between efficiency and performance. The denominator N in equation (1) specifies the number of sample periods Tsam required to scan a full period of input clock signal CKin, and thus generate a measure of the duty cycle of clock signal CKin. Greater values of N provide improved measurement precision, but require more sample periods—and thus more time—to acquire a measure of duty cycle. N can also have positive fractional values, and can be an integer. A full measure of duty cycle can be taken using N samples, but other numbers might also be used depending upon the desired measurement accuracy and the time available to perform a duty-cycle measurement. If N is one thousand, for example, taking N±1 samples would introduce a relatively small error. In general, the number of samples taken can be varied depending on a desired measurement accuracy. Multiples of N samples can also be used, but the requisite additional measurement interval is undesirable in some embodiments.

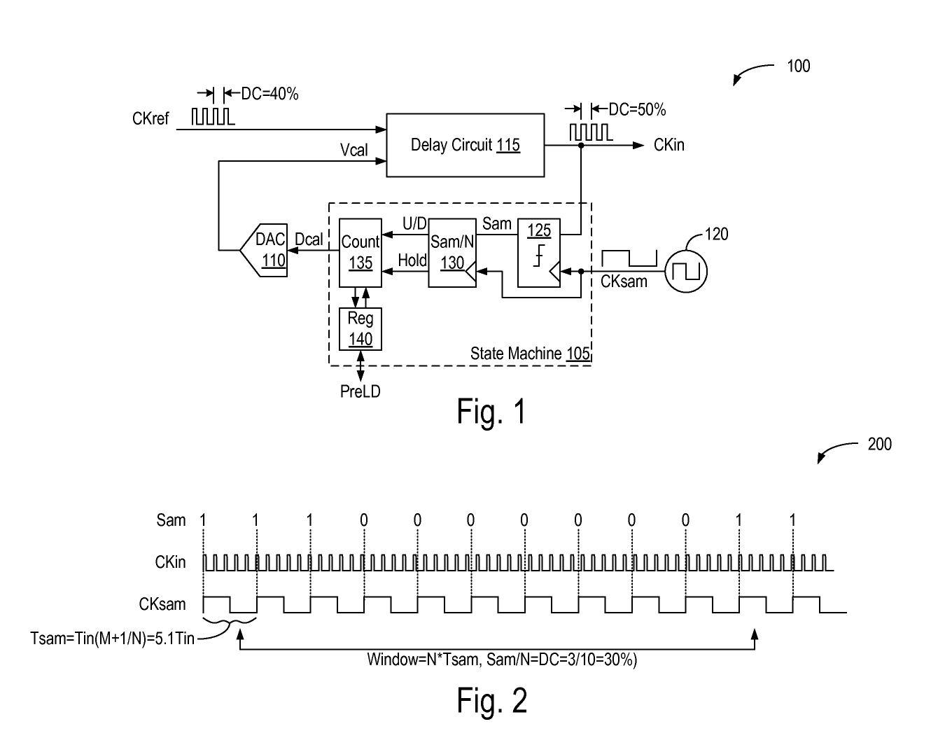

FIG. 2 is a waveform diagram 200 illustrating the operation of an embodiment of state machine 105 of FIG. 1. Clock signal CKin has a 30% duty cycle in this example, rather than the corrected 50% duty cycle of FIG. 1. Signal Sam is the output of sampler 125. Sampler 125 samples clock signal CKin on each rising edge of sample clock signal CKsam and outputs a signal level representative of a logic one (zero) when the sampled clock signal is relatively high (low). Accumulator 130 accumulates the number of samples Sam representative of a logic one over N periods Tsam, a ten-period window in this example.

Because the sample period Tsam includes the fractional value 1/N, the phase shift between clock signals CKsam and CKin increments by Tin/N for each period Tsam, and signal CKsam can be used to sub-sample CKin to measure its duty cycle. As a result, N successive samples taken over N sample periods Tsam represent a scan of one period Tin of the input clock signal. In the instant example, ten samples are taken over ten sample periods, and each sample instant is offset relative to signal CKin by an additional 1/10 of the period Tin. Three of the ten samples Sam are logic one, which indicates a duty cycle of 3/10, or 30%.

The sample window can begin on any edge of sample clock signal CKsam without impacting the measure of duty cycle. With reference to the specific example of FIG. 2, moving the highlighted window N*Tsam right or left along the timeline and relative to signal CKin gives the same sample ratio Sam/N of 3/10. Further, taking N samples ensures a complete scan for a period of input signal CKin. A reliable duty-cycle assessment is therefore available after a deterministic measurement period.

Accumulator 130 stores the ratio of samples to sampler periods (Sam/N), and consequently provides a measure of duty cycle. State machine 105 uses this information to correct duty-cycle errors. Assuming a 50% duty cycle is desired, for example, accumulator 130 can issue a hold signal Hold to counter 135 if the value Sam/N is 5. If Sam/N is greater than five, accumulator 130 can de-assert the hold signal and assert up/down signal U/D, causing counter 135 to increment. If Sam/N is less than 5, accumulator 130 de-asserts the hold signal and signal U/D, causing counter 135 to decrement. Digital calibration signal Dcal thus increments or decrements as needed to make duty-cycle corrections.

In this embodiment DAC 110 converts digital signal Dcal to an analog calibration voltage Vcal that adjusts the relative delays imposed by delay circuit 115 on rising and falling edges. In the example of FIG. 2, clock signal CKin has a 30% duty cycle, which indicates that the falling edges occur too quickly following rising edges. Signal Vcal is therefore adjusted to delay the falling edges relative to the rising edges, advance the rising edges relative to the falling edges, or both, to more evenly distribute the rising and falling edges.

State machine 105 can continuously or periodically measure duty cycle and provide the appropriate feedback as needed to correct for changes that can result from e.g. supply-voltage and temperature variations. Register 140 can store the calibrated value for the count stored in counter 135 to expedite duty-cycle calibration when DCCC 100 is enabled or powered on. In some embodiments register 140 can be loaded, via a preload signal PreLD, to speed calibration, or can be read from for test purposes or to store the calibration value elsewhere. Accumulator 130 may also be configurable, and a register (not shown) may be included to store the value N and the desired number of “one” samples. Finer measurement granularity might be obtained, for example, by setting N equal to 100 and sample period Tsam to Tin(M+ 1/100).

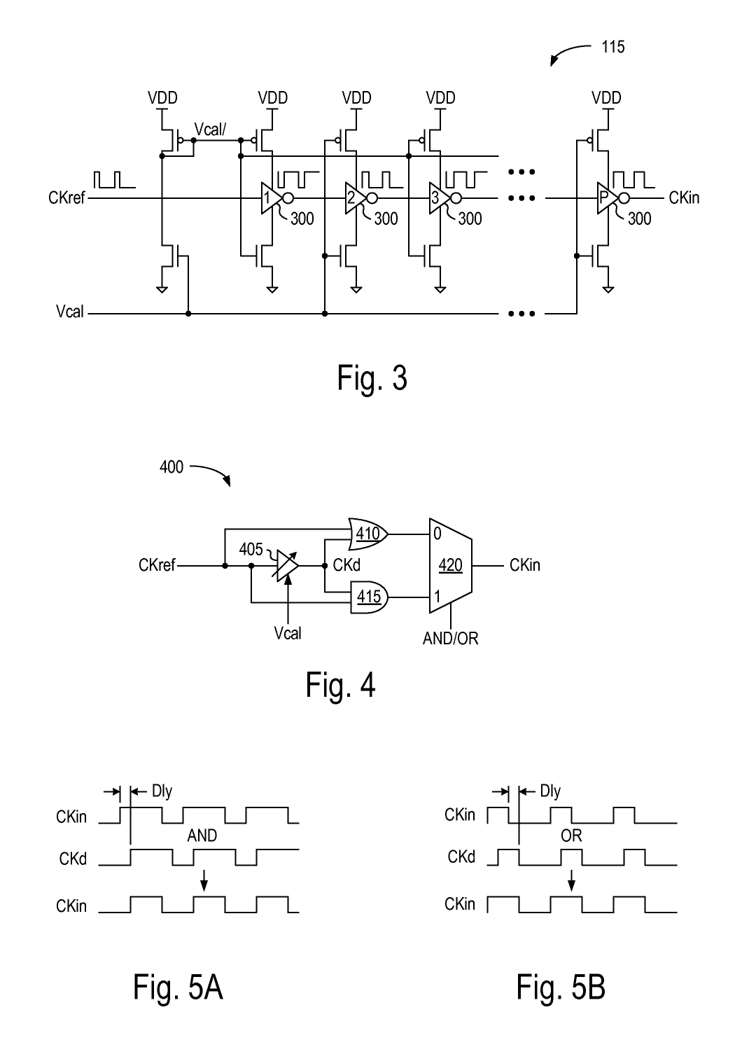

FIG. 3 depicts an embodiment of delay circuit 115 of FIG. 1, which includes a series of current-starved inverters 300. The rise and fall times for the output of each inverter 300 are controlled by respective PMOS and NMOS transistors. The gates of the transistors controlling the even-numbered inverters receive calibration voltage Vcal. As a consequence, the fall times (rise times) for the even-numbered inverters increase (decrease) with voltage Vcal. The gates of the transistors controlling the odd-numbered inverters receive a second calibration voltage Vcal/that rises and falls in inverse proportion to Vcal. The fall times (rise times) for the odd-numbered inverters thus decrease (increase) with voltage Vcal.

Assume, for example, that clock signal CKref has a duty cycle of less than a desired 50%. Delay circuit 115 with an even number of stages (P is even), can be used to “stretch” the relatively high portion of each clock period by both advancing the rising edges and delaying the falling edges. This can be accomplished by decreasing voltage Vcal, and consequently increasing voltage Vcal/. The increase in voltage Vcal/ to the odd-numbered inverters increases their response to rising edges of the input and decreases their response to input falling edges. The concomitant decrease in Vcal has the opposite effect on the even-numbered inverters. The inputs to the even-numbered inverters are inverted relative to the inputs to the odd-numbered inverters, however, so the even-numbered inverters enhance the effects of the odd-numbered inverters. Delay circuit 115 thus increases the duty cycle of clock signal CKin responsive to reductions in voltage Vcal, and vice versa, in this embodiment. In embodiments in which voltages Vcal and Vcal/ control the odd-numbered and even-numbered inverters, respectively, duty cycle increase responsive to increases in Vcal.

FIG. 4 depicts a duty-cycle adjustment circuit 400 that can be used in place of delay circuit 115 of FIG. 1 in one embodiment. Adjustment circuit 400 includes a variable delay circuit 405, an OR gate 410, an AND gate 415, and a multiplexer 420. Delay circuit 405 delays clock signal CKref by an amount proportional to calibration voltage Vcal to produce a delayed clock signal CKd.

If the duty cycle of signal CKref is greater than 50%, then signal AND/OR to multiplexer 420 is asserted. Clock signal CKin is therefore the AND of reference and delayed clock signals CKref and CKd. As depicted in FIG. 5A, the delay Dly through circuit 405 is adjusted such that the AND of those two signals has a 50% duty cycle. If the duty cycle of signal CKref is less than 50%, then signal AND/OR to multiplexer 420 is de-asserted. Clock signal CKin is therefore the OR of reference and delayed clock signals CKref and CKd. As depicted in FIG. 5B, the delay Dly through circuit 405 is adjusted such that the OR of those two signals has a 50% duty cycle. In one embodiment reference clock CKref can be selectively provided to the input of sampler 125 in lieu of signal CKin to allow state machine 105 to measure the duty cycle of reference clock signal CKref, and thus to select between the AND and OR functions.

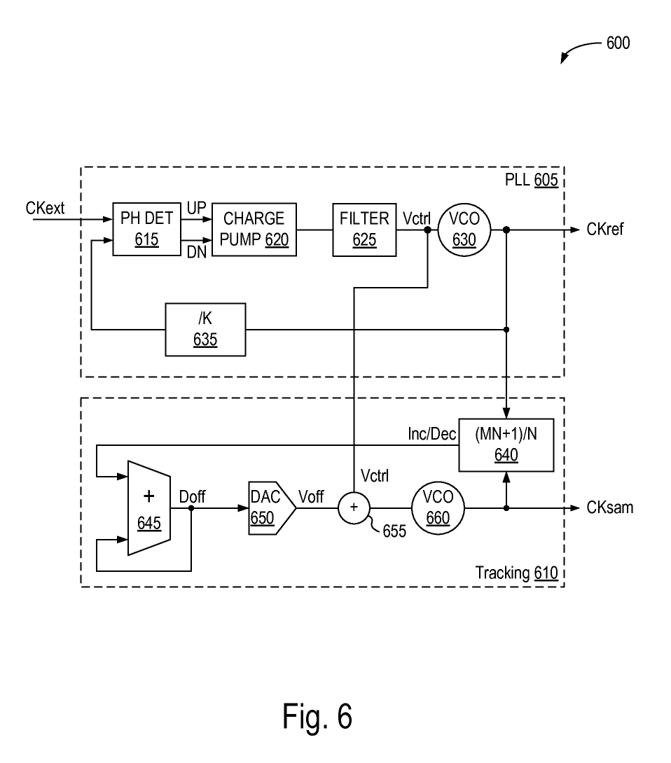

FIG. 6 depicts a timing circuit 600 for generating sample clock signals CKref and CKsam in accordance with one embodiment. In the embodiment of FIG. 1, sample clock CKsam has a period Tsam that is M+1/N times the clock period Tin of clock signal CKin. Period Tin is the same as the period Tref or reference clock signal CKref, so sample period Tsam can be set to Tref(M+1/N). Timing circuit 600 fixes this desired relationship between the sample and reference clock signals, and therefore between the sample and input clock signals.

Timing circuit 600 includes a phase-locked loop (PLL) 605 and sample-clock tracking circuitry 610. PLL 605 is conventional, so a detailed discussion is omitted. Briefly, PLL 605 includes a phase detector 615, a charge pump 620, a low-pass filter 625, and a voltage-controlled oscillator (VCO) 630 placed in a negative feedback configuration. A frequency divider 635 may be included in the feedback path between the output of VCO 630 and phase detector 615 to make the frequency of reference clock signal CKref a multiple of a signal CKext. Clock signal CKext may be e.g. a reference clock signal supplied from a reference source external to an integrated circuit.

Tracking circuit 610 includes a divider 640, an accumulator 645, a DAC 650, an adder 655, and a VCO 660. Divider 640 includes a pair of counters (not shown) that accumulate the numbers of signal transitions for each of clock signals CKref and CKsam over a designated sample period. In the example in which Tsam=Tref(M+1/N), the ratio of frequencies Fref/Fsam ideally equals (MN+1)/N. Recalling that M is 5 and N is 10 in the example of FIG. 1, divider 640 ideally senses a ratio of 51/10. If the ratio is not 51/10, then tracking circuit 610 adjusts the frequency of sample clock signal CKsam to counteract such errors.

Divider 640 asserts a signal Inc/Dec to accumulator 645 if the sensed ratio exceeds (MN+1)/N. Accumulator 645 responds by incrementing its output Doff to DAC 650, which in turn increases offset voltage Voff. Adder 655 adds signal Voff and control voltage Vctrl from PLL 605. The increased offset voltage Voff increases the sum of voltages provided to VCO 660, causing VCO 660 to increase the frequency of sample clock signal CKsam, and therefore to reduce the sample period Tsam. Divider 640 de-asserts signal Inc/Dec if the sensed ratio falls below (MN+1)/N, leading to an increase in sample period Tsam. Control signal Vctrl from PLL 605 is shared in this embodiment so that VCO 660 tracks VCO 630 once the correct ratio is established. While adder 655 and the associated input from filter 625 are not absolutely necessary, they help in reducing the gain Kvco of VCO 660 and providing better accuracy for sampling clock CKsam. Timing circuit 600 can be instantiated entirely on an integrated circuit, or all or part can be located off-chip. In some embodiments, for example, either of both of the sample and reference clock signals can be developed off chip.

An output of a process for designing an integrated circuit, or a portion of an integrated circuit, comprising one or more of the circuits described herein may be a computer-readable medium such as, for example, a magnetic tape or an optical or magnetic disk. The computer-readable medium may be encoded with data structures or other information describing circuitry that may be physically instantiated as an integrated circuit or portion of an integrated circuit. Although various formats may be used for such encoding, these data structures are commonly written in Caltech Intermediate Format (CIF), Calma GDS II Stream Format (GDSII), or Electronic Design Interchange Format (EDIF). Those of skill in the art of IC design can develop such data structures from schematic diagrams of the type detailed above and the corresponding descriptions and encode the data structures on computer readable medium. Those of skill in the art of integrated circuit fabrication can use such encoded data to fabricate integrated circuits comprising one or more of the circuits described herein.

While the present invention has been described in connection with specific embodiments, variations of these embodiments will be obvious to those of ordinary skill in the art. For example, while the presented duty cycle corrector circuit embodiment uses single ended inverters, similar ideas can be used for differential delay elements. Moreover, some components are shown directly connected to one another while others are shown connected via intermediate components. In each instance the method of interconnection, or “coupling,” establishes some desired electrical communication between two or more circuit nodes, or terminals. Such coupling may often be accomplished using a number of circuit configurations, as will be understood by those of skill in the art. Therefore, the spirit and scope of the appended claims should not be limited to the foregoing description. Only those claims specifically reciting “means for” or “step for” should be construed in the manner required under the sixth paragraph of 35 U.S.C. §112.

What is claimed is:

1. A circuit comprising:
a clock node to receive a clock signal having an clock period and a duty cycle;
a sample-signal node to receive a sampling signal having a sample-signal period (M±1/N) times the clock period, wherein M is a positive integer and N is a positive number; and
a state machine coupled to the clock node and the sample-signal node, the state machine to obtain samples of the clock signal in time with the sample signal over sufficient periods of the sample signal to obtain a desired measurement accuracy of the duty cycle, and to generate a measure of the duty cycle of the desired measurement accuracy based on the samples.

2. The circuit of claim 1, wherein the state machine samples the clock signal over at least N periods of the sample signal to generate the measure of the duty cycle.

3. The circuit of claim 1, wherein the state machine samples the clock signal over exactly N periods of the sample signal to generate the measure of the duty cycle.

4. The circuit of claim 1, wherein M is one.

5. The circuit of claim 1, further comprising a reference-clock node to receive a reference-clock signal and a variable-delay element disposed between the reference-clock node and the clock node, the variable-delay element including a control input coupled to the state machine to receive the measure of the duty cycle.

6. The circuit of claim 5, wherein the variable-delay element adjusts the duty cycle of the clock signal responsive to the measure of the duty cycle.

7. The circuit of claim 1, further comprising a register to preserve the measure of the duty cycle.

8. The circuit of claim 1 instantiated on an integrated circuit die and further comprising a sample-signal generator to generate the sample signal.

9. The circuit of claim 8, wherein the sample-signal generator comprises a locked-loop circuit.

10. The circuit of claim 1, wherein N is an integer.

11. The circuit of claim 1, the state machine further comprising a control port to issue a calibration signal based on the measure of the duty cycle.

12. The circuit of claim 11, further comprising an adjustable delay circuit having a reference node to receive a reference clock signal, a control port to receive the calibration signal, and an output port coupled to the clock node to provide the first-mentioned clock signal.

13. The circuit of claim 12, wherein the adjustable delay circuit comprises a series of current-controlled delay elements having control terminals coupled to the control port to receive the calibration signal.

14. The circuit of claim 1, wherein the calibration signal comprises an analog voltage, the delay elements include pull-up controlled delay elements and pull-down delay elements, and the analog voltage controls the current through both the pull-up and pull-down controlled delay elements.

15. A method comprising:
receiving, on a clock node, a clock signal having an clock period and a duty cycle;
sampling, with a sampler, the clock signal with a sample signal having a sample-signal period (M+1/N) times the clock period, wherein M is a non-zero integer, to acquire samples; and
adjusting the duty cycle responsive to the samples.

16. The method of claim 15, wherein the adjusting is responsive to a multiple of N of the samples.

17. The method of claim 16, wherein the multiple equals one.

18. The method of claim 15, wherein the samples includes first samples representative of a first logic level and second samples representative of a second logic level, the method further comprising storing a value representative of a ratio of the numbers of the first and second samples.

19. The method of claim 18, further comprising adjusting the duty cycle responsive to the value.

20. The method of claim 19, further comprising disabling at least one of the clock signal and the sample signal for a time while retaining the value, enabling the disabled at least one, and adjusting the duty cycle responsive to the retained value.

21. A computer-readable medium having stored thereon a data structure defining at least a portion of an integrated circuit, the data structure comprising:
first data representing a clock node to receive a clock signal having a clock period and a duty cycle;
second data representing a sample-signal node to receive a sample signal having a sample-signal period (M±1/N) times the clock period, wherein M is a positive integer and N is a positive number; and
third data representing a state machine coupled to the clock node and the sample-signal node, the state machine to obtain samples of the clock signal in time with the sample signal over sufficient periods of the sample signal to obtain a desired measurement accuracy of the duty cycle, and to generate a measure of the duty cycle of the desired measurement accuracy based on the samples.

22. The medium of claim 21, further comprising fourth data representing a reference-clock node to receive a reference-clock signal and a variable-delay element disposed between the reference-clock node and the clock node, the variable-delay element including a control input coupled to the state machine to receive the measure of the duty cycle.

23. The medium of claim 22, the variable-delay element to adjust the duty cycle of the clock signal responsive to the measure of the duty cycle.

24. The medium of claim 21, wherein the state machine samples the clock signal over at least N periods of the sample signal to generate the measure of the duty cycle.

25. The medium of claim 21, wherein the state machine samples the clock signal over exactly N periods of the sample signal to generate the measure of the duty cycle.

26. An integrated circuit comprising:
means for receiving, on a clock node, a clock signal having an clock period and a duty cycle;
a sampler for sampling the clock signal with a sample signal having a sample-signal period (M±1/N) times the clock period, wherein M is a positive integer and N is a positive number, to acquire samples; and
means for adjusting the duty cycle responsive to the samples.

27. The integrated circuit of claim 26, wherein the means for adjusting adjusts the duty cycle responsive to a multiple of N of the samples.

28. A method for calculating a duty cycle of a clock signal on an integrated circuit, the method comprising:
receiving, at a clock node, a clock signal having a clock period and the duty cycle;
periodically sub-sampling the clock signal, with a sampler, to acquire multiple samples of the clock signal over multiple clock periods of the clock signal; and
adjusting the duty cycle in response to the multiple samples.

29. The method of claim 28, wherein periodically sub-sampling the clock signal comprises applying a sample signal of a sample period (M±1/N) to the sampler, wherein M is an integer.

30. The method of claim 29, further comprising adjusting the duty cycle responsive to an integer multiple of N of the samples.

31. The method of claim 30, further comprising adjusting the duty cycle responsive to N of the samples.
